(19) United States
(12) Patent Application Publication
(10) Pub. No.: US 2022/0237454 A1
(43) Pub. Date: Jul. 28, 2022

(54) LINEAR NEURAL RECONSTRUCTION FOR DEEP NEURAL NETWORK COMPRESSION

(71) Applicant: InterDigital VC Holding, Inc., Wilmington, DE (US)

(72) Inventors: Swayambhoo Jain, Milpitas, CA (US); David A. R. Robin, Le Plessis-Robinson (FR)

(21) Appl. No.: 17/612,528

(22) PCT Filed: May 20, 2020
(86) PCT No.: PCT/US2020/033867

§ 371 Date: Nov. 18, 2021

Related U.S. Application Data
(60) Provisional application No. 62/850,586, filed on May 21, 2019.

(51) Int. Cl. G06N 3/08

(52) U.S. Cl. CPC G06N 3/08

(57) ABSTRACT

A method and apparatus for performing deep neural network compression of convolutional and fully connected layers using a linear approximation of their outputs with information, such as in matrices representing weights, biases and non-linearities, to iteratively compress a pre-trained deep neural network by low displacement rank based approximation of the network layer weight matrices. Extension of the technique enables consecutive layers to be compressed jointly, allowing compression and speeding inference by reducing the number of channels/hidden neurons in the network.

### TECHNICAL FIELD

At least one of the present embodiments generally relates to a method or an apparatus for machine learning.

### BACKGROUND

Deep Neural networks (DNNs) have demonstrated great empirical success in a wide range of machine-learning tasks. Recent work has started to show that their overparameterization allows them to provably reach global optima when training. The resulting networks however exhibit high levels of redundancy. While overparameterization might be beneficial during the training, it is not mandatory to retain so much redundancy to achieve accuracy. Model compression seeks to compute light-weight approximations of large trained neural networks to curb the storage requirements while maintaining prediction accuracy.

### SUMMARY

Drawbacks and disadvantages of the prior art may be addressed by the general aspects described herein, which are directed to linear neural reconstruction for deep neural network (DNN) compression.

According to a first aspect of the disclosure, there is provided a method. The method comprises steps for determining neural network training data from a neural network data set, obtaining inputs and outputs of layers of a neural network based on the neural network training data compressing at least one layer of the neural network using said inputs and outputs to obtain parameters representing weights and biases corresponding to said layers, and storing or transmitting said compressed parameters in a bitstream.

According to an embodiment, said neural network training data is obtained based on a subset of training data used for training the neural network.

According to an embodiment, said weights and biases corresponding to the layers of the neural network are quantized.

According to an embodiment, said neural network training data comprises set examples on the neural network.

According to an embodiment, said bitstream further comprises metadata indicative of non-linearities.

According to an embodiment, said compression is performed for a fixed number of layers.

According to a second aspect, there is provided a method. The method comprises steps for extracting symbols from a bitstream, inverse quantizing said symbols; obtaining matrix weights for at least one neural network layer from said so inverse quantized symbols, and, reconstructing a neural network from said matrix weights for the at least one neural network layer.

According to another aspect, there is provided an apparatus. The apparatus comprises a processor. The processor can be configured to determine neural network training data from a neural network data set, obtain inputs and outputs of is layers of a neural network based on the neural network training data, compress at least one layer of the neural network using said inputs and outputs to obtain parameters representing weights and biases corresponding to said layers, and store or transmitting said compressed parameters in a bitstream.

According to an embodiment, said neural network training data is obtained based on a subset of training data used for training the neural network.

According to an embodiment, said weights and biases corresponding to the layers of the neural network are quantized.

According to an embodiment, said neural network training data comprises set examples on the neural network.

According to an embodiment, said bitstream further comprises metadata indicative of non-linearities.

According to an embodiment, said compression is performed for a fixed number of layers.

According to another aspect, there is provided an apparatus. The apparatus comprises a processor. The processor can be configured to extract symbols from a bitstream, inverse quantize said symbols, obtain matrix weights for at least one neural network layer from said inverse quantized symbols, and reconstruct a neural network from said matrix weights for the at least one neural network layer.

According to another general aspect of at least one embodiment, there is provided a device comprising an apparatus according to any of the decoding embodiments; and at least one of (i) an antenna configured to receive a signal, the signal including information corresponding to a compressed deep neural network, (ii) a band limiter configured to limit the received signal to a band of frequencies that includes the signal, or (iii) a display configured to display an output representative of the signal.

Some processes implemented by elements of the disclosure may be computer implemented. Accordingly, such elements may take the form of an entirely hardware so embodiment, an entirely software embodiment (including firmware, resident software, microcode, etc.) or an embodiment combining software and hardware aspects that may all generally be referred to herein as “circuit”, “module” or “system”. Furthermore, such elements may take the form of a computer program product embodied in any tangible medium of expression having computer usable program code embodied in is the medium.

Since elements of the disclosure can be implemented in software, the present disclosure can be embodied as computer readable code for provision to a programmable apparatus on any suitable carrier medium. A tangible carrier medium may comprise a storage medium such as a floppy disk, a CD-ROM, a hard disk drive, a magnetic tape device or a solid-state memory device and the like. A transient carrier medium may include a signal such as, an electrical signal, an optical signal, an acoustic signal, a magnetic signal or an electromagnetic signal, e.g., a microwave or RF signal.

These and other aspects, features and advantages of the general aspects will become apparent from the following detailed description of exemplary embodiments, which is to be read in connection with the accompanying drawings.

### BRIEF DESCRIPTION OF THE DRAWINGS

Other features and advantages of embodiments shall appear from the following description, given by way of indicative and non-exhaustive examples and from the appended drawings, of which:

FIG. 1 illustrates an exemplary pipeline for low displacement rank based neural network compression according to an embodiment of the disclosure;

FIG. 2 illustrates details for the exemplary linear neural reconstruction-based approximation sub-block of FIG. 1, according to an embodiment of the disclosure;

FIG. 3 shows an exemplary flow diagram for determining linear neural reconstruction-based approximation of Deep Neural Network (DNN) layers at the encoder according to an embodiment of the disclosure;

FIG. 4 shows an exemplary flow diagram for a training loop for linear neural reconstruction shown in FIG. 3, according to an embodiment of the disclosure;

FIG. 5 shows an exemplary flow diagram of a proposed decoding process according to an embodiment of the disclosure;

FIG. 6 shows an exemplary flow diagram of a proposed encoding process according to an embodiment of the disclosure;

FIG. 7 shows an exemplary flow diagram of another proposed decoding process according to an embodiment of the disclosure;

FIG. 8 illustrates an exemplary apparatus including a typical processor arrangement in which the herein described embodiments may be implemented; and

FIG. 9 illustrates an exemplary system in which the herein described embodiments may be implemented.

### DETAILED DESCRIPTION

Deep Neural networks (DNNs) have demonstrated great empirical success in a wide range of machine-learning tasks. Recent work has started to show that their overparameterization allows them to provably reach global optima when training. The resulting networks however exhibit high levels of redundancy. While overparameterization might be beneficial during the training, it is not mandatory to retain so much redundancy to achieve accuracy.

From an architecture design point of view, it is also much easier to overparameterize an architecture without thinking about the associated complexity and defer memory concerns to a later design stage. In this regard, during both the architecture design stage and for the transmission and storage of pre-trained networks, model compression seeks to compute light-weight approximations of large trained neural networks to curb storage requirements, while maintaining accuracy.

The disclosure applies to compression of convolutional and fully connected layers. The compression of such layers occurs via a linear approximation of their outputs from an automatically selected subset of their input. The present disclosure extends this technique to take advantage of consecutive layers to compress them jointly better than they would have been compressed independently by the same technique. This leads to speeding up inference by reducing the number of channels/hidden neurons in the network.

Deep Neural Networks (DNNs) have shown state of the art performance in a variety of domains such as, for example, computer vision, speech recognition, natural language processing, etc. This performance however comes at the cost of massive computational investment, as DNNs tend to have a large number of parameters often running into millions, and sometimes even billions. This leads to prohibitively high inference complexity—the computational cost of applying trained DNN to test data for inference. This high inference complexity is the main challenge in bringing the performance of DNNs to mobile or embedded devices which have resource limitations on battery size, computational power, and memory capacity, etc.

Most compression techniques for deep neural networks rely on an approximability assumption on the weight matrix, either by a sparse matrix or a low-rank matrix. The sparse matrix reduces the number of non-zero weights, but keeps the weight matrix dimensions identical, enabling CSR-like encoding (Compressed Sparse Row encodings for sparse matrices) that results in an overhead induced by the storage of the indices of non-zero weights. The present disclosure builds on the low-rank matrix by restricting the search space to low-rank matrices of a certain form to tackle the index overhead issue by ensuring that the low-rank approximation can be converted into substantial storage gains by reducing the dimension of weight matrices both before and after the non-linearities.

Although these approximations are still within a subset of low-rank matrices, this restriction makes them actually more effective in terms of compression than other low-rank approximations, mainly because those use a feature extractor whose action does not commute the non-linearities, requiring both the feature extractor and the reconstructor to be stored. In contrast, the present approach uses a feature selector in place of the linear feature extractor, requiring only the reconstructor to be stored, because the feature selector can be applied before the non-linearity, collapsing with the previous layer weight matrix and inducing a reduction of dimension in both weight matrices.

While the aforementioned approaches lead to compression, they still suffer from the high inference complexity. The sparsity structure is difficult to implement in hardware as the performance depends critically on the pattern of sparsity, and the existing approaches do not have any control over the sparsity pattern. The low-rank matrices are still unstructured. For these reasons, such approaches do not necessarily lead to improvement in the inference complexity. The LDR based approximation proposed in this disclosure approximates the given layer weight matrix as a sum small number of structured matrices which allows for simultaneous compression and low inference complexity.

In the present disclosure, the compression is discussed in detail for fully connected layers, and it is extended to channel-pruning of convolutional layers as a variant. In an exemplary embodiment, there is provided an L-Layer pre-trained DNN with weight matrices {W₁, . . . , W_{L}}, biases {b₁, . . . b_{L}}, and non-linearities {g₁, . . . , g_{L}}. With these weights, biases, and non-linearities, the output of k^{th} layer y^{k+1} is written as [where y¹=x is the input to the DNN]

y^{k+1}=gₖ(Wₖyₖ+bₖ)

In this example, we propose to approximate the layers of pre-trained DNN {W₁, . . . , W_{L}} with matrices {Ŵ₁, . . . , Ŵ_{L}} such that these matrices have all zero-columns. The zero-columns lead to substantial compression. In order to carefully select the non-zero columns in a trainable automated fashion, we use approximation training set [symbol] ={x₁, . . . , x_{T}}, which can be chosen as a subset of original training set used to train the given DNN, or it may be chosen as set examples on the DNN it is supposed to operate on. Using the approximation training set [symbol] , we can obtain the output and input of each layer of the original pre-trained DNN. The input of the k^{th} layer for a given example xₜ in the approximating set [symbol] is denoted as yₓ_{ₜ}^{k}. With this, the following optimization problem for k^{th} layer is solved as:

$${\hat{W}}_{k} = {argmin}_{M} [ {\sum }_{{x}_{t} ∈ χ} {‖ {W}_{k} {y}_{{x}_{t}}^{k} - M {y}_{{x}_{t}}^{k} ‖}_{2}^{2} ] + {λ}_{k} {‖ M ‖}_{2 , 1} \qquad ( 1 )$$

where λₖ≥0 are regularization parameters, wherein a larger value of λₖ leads to more zero-columns in Ŵₖ, and ∥M∥_{2,1} is the sum of [symbol] ₂ norms of columns of matrix M. This is a convex problem and can be solved using, for example, standard proximal gradient based algorithms.

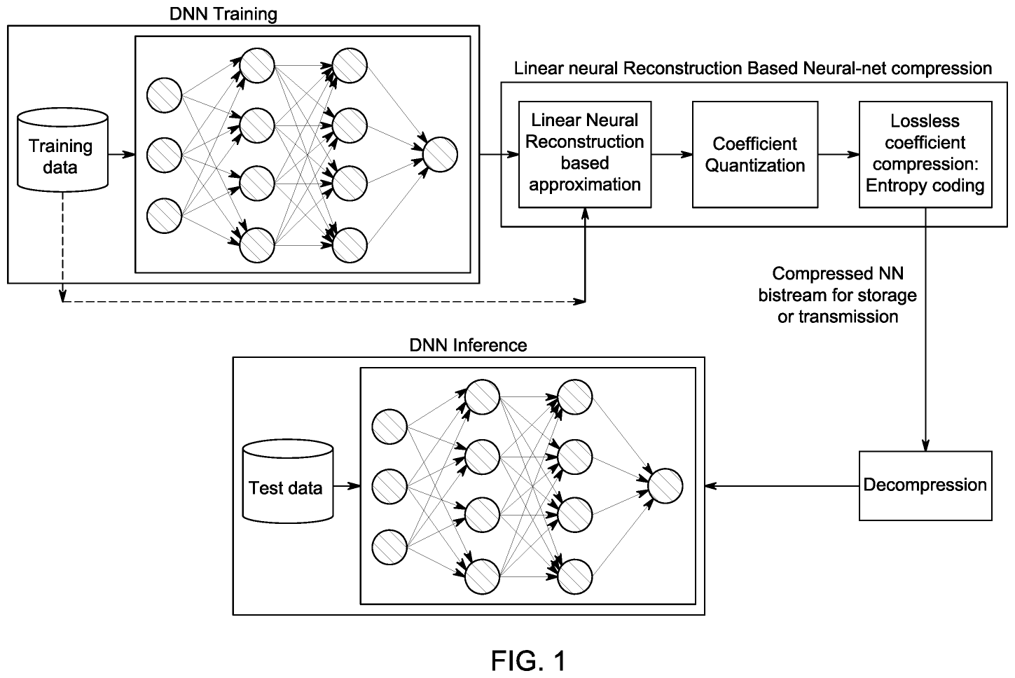

The overall architecture for compressing the neural network in the proposed embodiment, is shown in FIG. 1. FIG. 1 illustrates the DNN training stage that involves training a DNN on the given training data. Next block takes the pre-trained DNN represented by weight matrices {W₁, . . . , W_{L}}, biases {b₁, . . . , b_{L}}, and non-linearities {g₁, . . . , g_{L}} as the input, and the approximation training set [symbol] ={x₁, . . . , x_{T}}. The first sub-step in a proposed compression block is the linear neural reconstruction-based block, which is the object of this disclosure. After this each layer is compressed by solving equation (1) for each layer by choosing a desired λₖ to obtain {Ŵ₁, . . . , Ŵ_{L}}, and {\hat{b}₁, . . . , \hat{b}_{L}}. This coefficient may be optionally quantized followed by lossless coefficient compression for each layer. The resulting bitstream may be stored or transmitted. The compressed bitstream is decompressed using the metadata, and for inference the DNN is loaded into memory for inference on test data, for the application at hand.

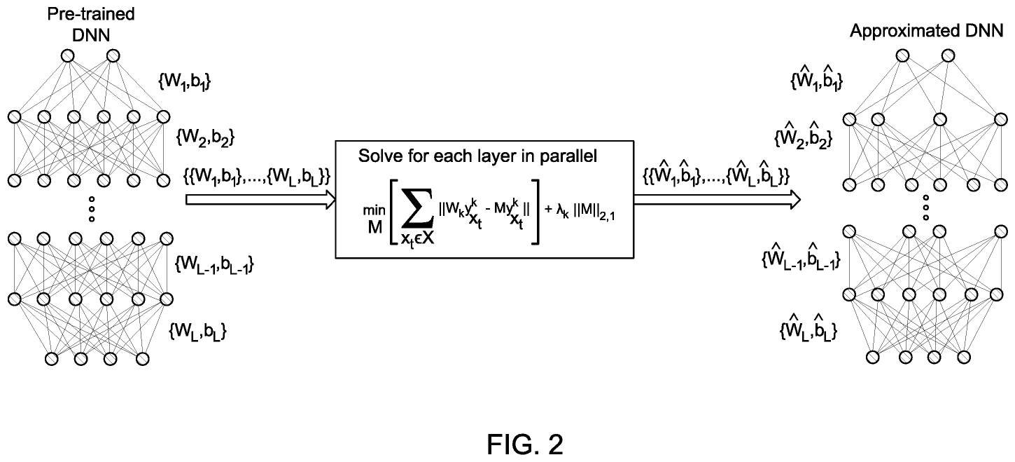

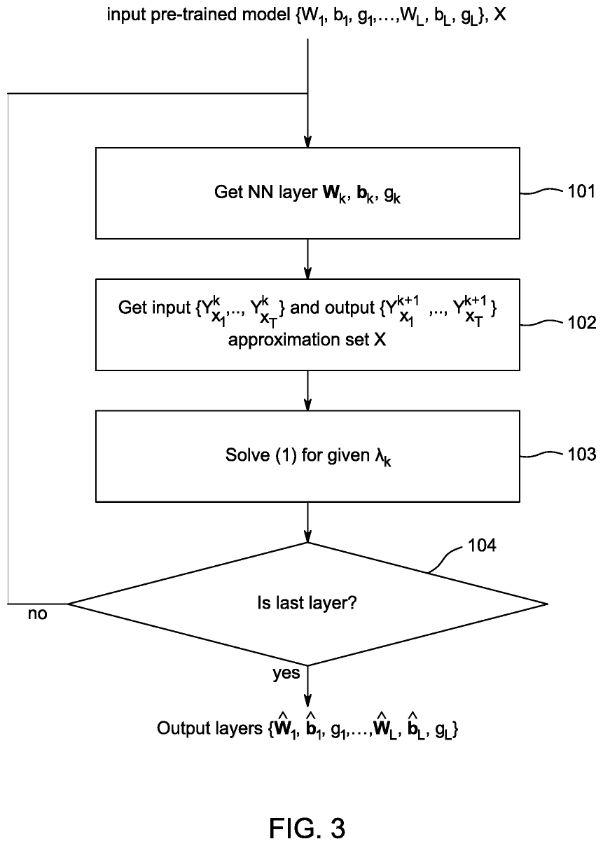

FIG. 2 shows the linear neural reconstruction-based approximation sub-block of FIG. 1 in detail. The approximation for each layer can be obtained in parallel, as shown in FIG. 2, using the approximation training set [symbol] ={x₁, . . . , x_{T}}. The linear neural reconstruction-based approximation at the encoder, is shown in FIG. 3. Using the approximation training set χ, we can obtain the output and input of each of the original pre-trained DNN. The input and output of the kₜₕ layer for a given example xₜ in the approximating set [symbol] are denoted as kₓ_{ₜ}^{k} and yₓ_{ₜ}^{k+1}. Each layer can be accessed at step 101, potentially in parallel, looping from step 104 depending on computer resources, until the last layer is processed. The approximations are obtained per layer, at step 102.

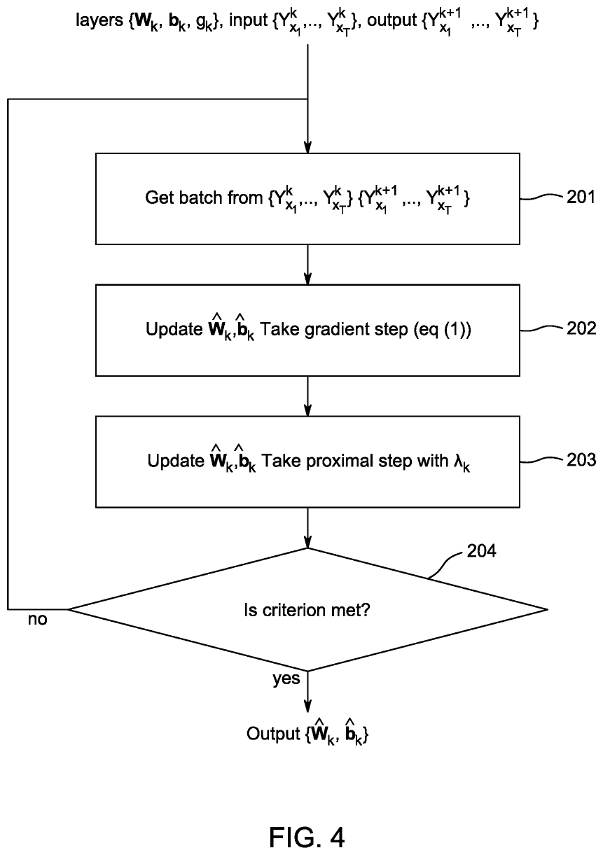

The step 103 is further described in FIG. 4. For each iteration, the current batch of input/output is accessed at step 201, a gradient step 202 is taken to minimize the reconstruction error from equation (1), and a proximal step is taken as described in 203. The stopping criterion at step 204 can be based on a fixed number of training iterations. Alternatively, the training can continue until the approximations updated in consecutive training steps are numerically close to each other, up to a chosen threshold.

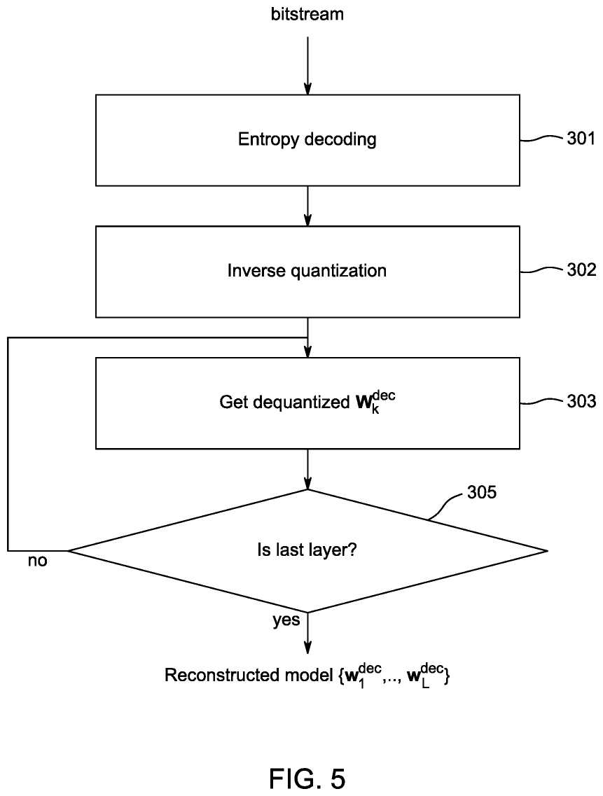

To decode the produced bitstream, a compatible decoder needs to perform the inverse compression steps. FIG. 5 details the inverse compression steps. The symbols of the input bitstream are first extracted from the entropy decoding engine at step 301, then inverse quantized at step 302. For each layer at step 305, the dequantized matrices are accessed at step 304, and each matrix Wₖ^{dec} obtained.

Hence, to decode and obtain the reconstructed DNN, decoders that would implement a standard compression scheme, such as, for example, the future MPEG NNR standard, will be required to use the disclosed method.

Some variants of the aforementioned method, under the general described exemplary embodiments follow.

In an alternative embodiment, if a previous layer is not fully connected, the approximated matrix [symbol] =PC^{T} can still be stored in a more compressed form than the original matrix W, by storing P, and the list of non-zero indices of C.

In another alternative embodiment, the compression method is a function that transforms a neural network, of a given architecture, into a smaller neural network of the same architecture, up to hidden neuron count modifications. For such an instance, any pre- and post-processing steps are still applicable, including but not limited to, retraining of the compressed network to improve its accuracy, pruning of all layer weights, quantization and clustering of weights, and any other approximation of weight matrices, or encoding of the compressed weight matrices.

In another alternative embodiment, the disclosed technique can be extended to channel pruning of convolutional layers by changing the regularization of equation (1) into a group Lasso type penalty, where groups are exactly input channels.

In an alternative embodiment, instead of computing all approximations in parallel, one may compute them sequentially, and use the reconstructed output of the previous layer instead of its true output as the input of the reconstruction described in FIG. 4.

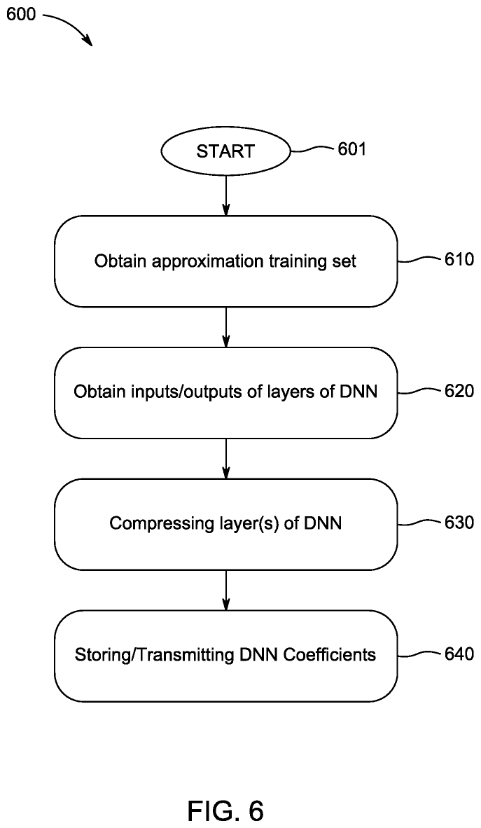

An exemplary embodiment of a method 600 utilizing the general aspects described herein, is shown in FIG. 6. The method commences at Start block 601 and control proceeds to function block 610 for obtaining an approximation training set. Control proceeds from block 610 to block 620 for obtaining inputs and outputs of layers of a pre-trained deep neural network (DNN). Control proceeds from block 620 to block 630 for compressing at least one layer of the deep neural network using the inputs and outputs to obtain coefficients representing weights and biases corresponding to layers of the deep neural network. Control proceeds from block 630 to block 640 for storing or transmitting the compressed coefficients in a bitstream.

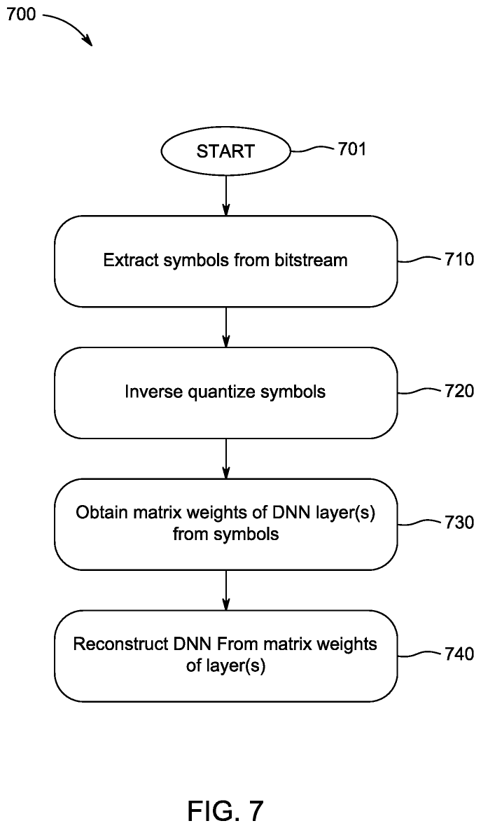

Another exemplary embodiment of a method 700 utilizing the general aspects described herein, is shown in FIG. 7. The method commences at Start block 701 and control proceeds to function block 710 for extracting symbols from a bitstream. Control proceeds from block 710 to block 720 for inverse quantizing the symbols. Control proceeds from block 720 to block 730 for obtaining matrix weights for at least one neural network layer from the inverse quantized symbols. Control proceeds from block 730 to block 740 for reconstructing a neural network from the matrix weights for the at least one neural network layer.

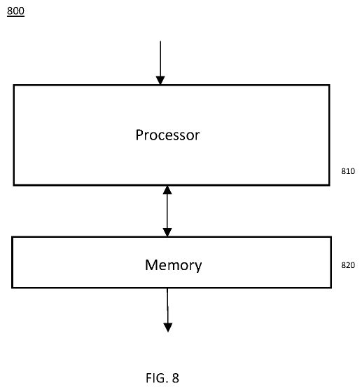

FIG. 8 illustrates an exemplary embodiment of an apparatus 800 for compressing, encoding or decoding a deep neural network in a bitstream. The apparatus comprises at least one processor 810 and can be interconnected to a memory 820 through at least one port. Both processor(s) 810 and memory 820 can also have one or more additional interconnections to external components.

Processor 810 is also configured to either insert or receive parameters in a bitstream and, either compressing, encoding or decoding a deep neural network using the parameters.

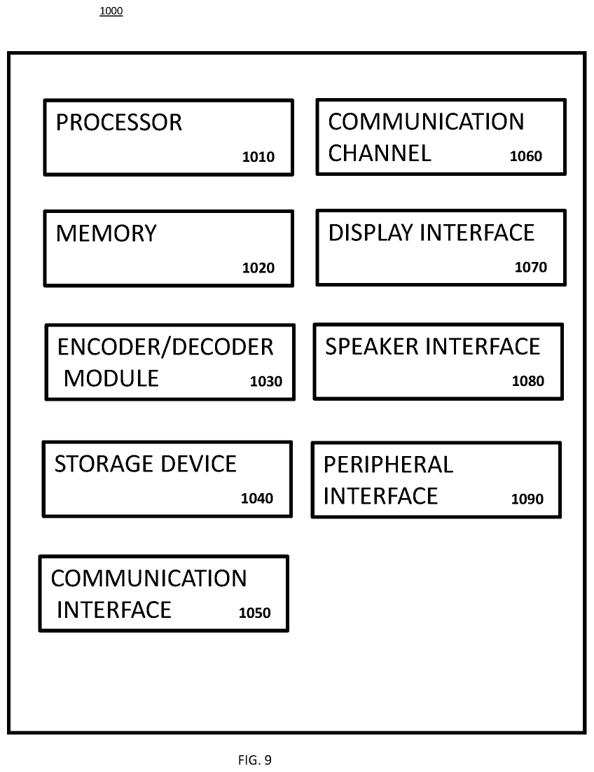

Referring to FIG. 9, a system is described for performing an exemplary embodiment. The system 1000 includes at least one processor 1010 configured to execute instructions loaded therein for implementing, for example, the various aspects described in this document. Processor 1010 can include embedded memory, input output interface, and various other circuitries as known in the art. The system 1000 includes at least one memory 1020 (e.g., a volatile memory device, and/or a non-volatile memory device). System 1000 includes a storage device 1040, which can include non-volatile memory and/or volatile memory, including, but not limited to, Electrically Erasable Programmable Read-Only Memory (EEPROM), Read-Only Memory (ROM), Programmable Read-Only Memory (PROM), Random Access Memory (RAM), Dynamic Random Access Memory (DRAM), Static Random Access Memory (SRAM), flash, magnetic disk drive, and/or optical disk drive. The storage device 1040 can include an internal storage device, an attached storage device (including detachable and non-detachable storage devices), and/or a network accessible storage device, as non-limiting examples.

System 1000 includes an encoder/decoder module 1030 configured, for example, to process data to provide an encoded video or decoded video, and the encoder/decoder module 1030 can include its own processor and memory. The encoder/decoder module 1030 represents module(s) that can be included in a device to perform the encoding and/or decoding functions. As is known, a device can include one or both of the encoding and decoding modules. Additionally, encoder/decoder module 1030 can be implemented as a separate element of system 1000 or can be incorporated within processor 1010 as a combination of hardware and software as known to those skilled in the art.

Program code to be loaded onto processor 1010 or encoder/decoder 1030 to perform the various aspects described in this document can be stored in storage device 1040 and subsequently loaded onto memory 1020 for execution by processor 1010. In accordance with various embodiments, one or more of processor 1010, memory 1020, storage device 1040, and encoder/decoder module 1030 can store one or more of various items during the performance of the processes described in this document. Such stored items can include, but are not limited to, the input video, the is decoded video or portions of the decoded video, the bitstream, matrices, variables, and intermediate or final results from the processing of equations, formulas, operations, and operational logic.

In some embodiments, memory inside of the processor 1010 and/or the encoder/decoder module 1030 is used to store instructions and to provide working memory for processing that is needed during encoding or decoding. In other embodiments, however, a memory external to the processing device (for example, the processing device can be either the processor 1010 or the encoder/decoder module 1030) is used for one or more of these functions. The external memory can be the memory 1020 and/or the storage device 1040, for example, a dynamic volatile memory and/or a non-volatile flash memory. In several embodiments, an external non-volatile flash memory is used to store the operating system of, for example, a television. In at least one embodiment, a fast external dynamic volatile memory such as a RAM is used as working memory for video coding and decoding operations, such as for MPEG-2 (MPEG refers to the Moving Picture Experts Group, MPEG-2 is also referred to as ISO/IEC 13818, and 13818-1 is also known as H.222, and 13818-2 is also known as H.262), HEVC (HEVC refers to High Efficiency Video Coding, also known as H.265 and MPEG-H Part 2), or VVC (Versatile Video Coding, a new standard being developed by JVET, the Joint Video Experts Team).

The input to the elements of system 1000 can be provided through various input devices (not shown). Such input devices include, but are not limited to, (i) a radio frequency (RF) portion that receives an RF signal transmitted, for example, over the air by a broadcaster, (ii) a Component (COMP) input terminal (or a set of COMP input terminals), (iii) a Universal Serial Bus (USB) input terminal, and/or (iv) a High Definition Multimedia Interface (HDMI) input terminal. Other examples may include, for example, composite video.

In various embodiments, the input devices have associated respective input processing elements as known in the art. For example, the RF portion can be associated with elements suitable for (i) selecting a desired frequency (also referred to as selecting a signal, or band-limiting a signal to a band of frequencies), (ii) downconverting the selected signal, (iii) band-limiting again to a narrower band of frequencies to select (for example) a signal frequency band which can be referred to as a channel in certain embodiments, (iv) demodulating the downconverted and band-limited signal, (v) performing error correction, and (vi) demultiplexing to select the desired stream of data packets. The RF portion of various embodiments includes one or more elements to perform these functions, for example, frequency selectors, signal selectors, band-limiters, channel selectors, filters, downconverters, demodulators, error correctors, and demultiplexers. The RF portion can include a tuner that performs various of these functions, including, for example, downconverting the received signal to a lower frequency (for example, an intermediate frequency or a near-baseband frequency) or to baseband. In one set-top box embodiment, the RF portion and its associated input processing element receives an RF signal transmitted over a wired (for example, cable) medium, and performs frequency selection by filtering, downconverting, and filtering again to a desired frequency band. Various embodiments rearrange the order of the above-described (and other) elements, remove some of these elements, and/or add other elements performing similar or different functions. Adding elements can include inserting elements in between existing elements, such as, for example, inserting amplifiers and an analog-to-digital converter. In various embodiments, the RF portion includes an antenna.

Additionally, the USB and/or HDMI terminals can include respective interface processors for connecting system 1000 to other electronic devices across USB and/or HDMI connections. It is to be understood that various aspects of input processing, for example, Reed-Solomon error correction, can be implemented, for example, within a separate input processing IC or within processor 1010 as necessary. Similarly, aspects of USB or HDMI interface processing can be implemented within separate interface ICs or within processor 1010 as necessary. The demodulated, error corrected, and demultiplexed stream is provided to various processing elements, including, for example, processor 1010, and encoder/decoder 1030 operating in combination with the memory and storage elements to process the datastream as necessary for presentation on an output device.

Various elements of system 1000 can be provided within an integrated housing, Within the integrated housing, the various elements can be interconnected and transmit data therebetween using suitable connection arrangement, for example, an internal bus as known in the art, including the Inter-IC (12C) bus, wiring, and printed circuit boards.

The system 1000 includes communication interface 1050 that enables communication with other devices via communication channel 1060. The communication interface 1050 can include, but is not limited to, a transceiver configured to transmit and to receive data over communication channel 1060. The communication interface 1050 can include, but is not limited to, a modem or network card and the communication channel 1060 can be implemented, for example, within a wired and/or a wireless medium.

Data is streamed, or otherwise provided, to the system 1000, in various embodiments, using a wireless network such as a Wi-Fi network, for example IEEE 802.11 (IEEE refers to the Institute of Electrical and Electronics Engineers). The Wi-Fi signal of these embodiments is received over the communications channel 1060 and the communications interface 1050 which are adapted for Wi-Fi communications. The communications channel 1060 of these embodiments is typically connected to an access point or router that provides access to external networks including the Internet for allowing streaming applications and other over-the-top communications. Other embodiments provide streamed data to the system 1000 using a set-top box that delivers the data over, for example, an HDMI connection. Still other embodiments provide streamed data to the system 1000 using an RF connection. As indicated above, various embodiments provide data in a non-streaming manner. Additionally, various embodiments use wireless networks other than Wi-Fi, for example a cellular network or a Bluetooth network.

The system 1000 can provide an output signal to various output devices, including a display (not shown), speakers (not shown), and other peripheral devices. The display may include one or more of, for example, a touchscreen display, an organic light-emitting diode (OLED) display, a curved display, and/or a foldable display. The display can be for a television, a tablet, a laptop, a cell phone (mobile phone), or another device. The display can also be integrated with other components (for example, as in a smart phone), or separate (for example, an external monitor for a laptop). The other peripheral devices may include, in various examples of embodiments, one or more of a stand-alone digital video disc (or digital versatile disc) (DVR, for both terms), a disk player, a stereo system, and/or a lighting system. Various embodiments use one or more peripheral devices that provide a function based on the output of the system 1000. For example, a disk player performs the function of playing the output of the system 1000.

In various embodiments, control signals are communicated between the system 1000 and a display, speakers, or other peripheral devices using signaling such as AV.Link, Consumer Electronics Control (CEC), or other communications protocols is that enable device-to-device control with or without user intervention. The output devices can be communicatively coupled to system 1000 via dedicated connections through respective interfaces 1070, 1080, and 1090. Alternatively, the output devices can be connected to system 1000 using the communications channel 1060 via the communications interface 1050. The display and speakers may be integrated in a single unit with the other components of system 1000 in an electronic device such as, for example, a television. In various embodiments, the display interface 1070 includes a display driver, such as, for example, a timing controller (T Con) chip.

The embodiments can be carried out by computer software implemented by the processor 1010 or by hardware, or by a combination of hardware and software. As a non-limiting example, the embodiments can be implemented by one or more integrated circuits. The memory 1020 can be of any type appropriate to the technical environment and can be implemented using any appropriate data storage technology, such as optical memory devices, magnetic memory devices, semiconductor-based memory devices, fixed memory, and removable memory, as non-limiting examples. The processor 1010 can be of any type appropriate to the technical environment, and can encompass one or more of microprocessors, general purpose computers, special purpose computers, and processors based on a multi-core architecture, as non-limiting examples.

Note that the syntax elements as used herein are descriptive terms. As such, they do not preclude the use of other syntax element names.

When a figure is presented as a flow diagram, it should be understood that it also provides a block diagram of a corresponding apparatus. Similarly, when a figure is presented as a block diagram, it should be understood that it also provides a flow diagram of a corresponding method/process.

Various embodiments may refer to parametric models or rate distortion optimization. In particular, during the encoding process, the balance or trade-off between the rate and distortion is usually considered, often given the constraints of computational complexity. It can be measured through a Rate Distortion Optimization (RDO) metric, or through Least Mean Square (LMS), Mean of Absolute Errors (MAE), or other such measurements. Rate distortion optimization is usually formulated as minimizing a rate distortion function, which is a weighted sum of the rate and of the distortion. There are different approaches to solve the rate distortion optimization problem. For example, the approaches may be based on an extensive testing of all is encoding options, including all considered modes or coding parameters values, with a complete evaluation of their coding cost and related distortion of the reconstructed signal after coding and decoding. Faster approaches may also be used, to save encoding complexity, in particular with computation of an approximated distortion based on the prediction or the prediction residual signal, not the reconstructed one. Mix of these two approaches can also be used, such as by using an approximated distortion for only some of the possible encoding options, and a complete distortion for other encoding options. Other approaches only evaluate a subset of the possible encoding options. More generally, many approaches employ any of a variety of techniques to perform the optimization, but the optimization is not necessarily a complete evaluation of both the coding cost and related distortion.

The implementations and aspects described herein can be implemented in, for example, a method or a process, an apparatus, a software program, a data stream, or a signal. Even if only discussed in the context of a single form of implementation (for example, discussed only as a method), the implementation of features discussed can also be implemented in other forms (for example, an apparatus or program). An apparatus can be implemented in, for example, appropriate hardware, software, and firmware. The methods can be implemented in, for example, a processor, which refers to processing devices in general, including, for example, a computer, a microprocessor, an integrated circuit, or a programmable logic device. Processors also include communication devices, such as, for example, computers, cell phones, portable/personal digital assistants (“PDAs”), and other devices that facilitate communication of information between end-users.

Reference to “one embodiment” or “an embodiment” or “one implementation” or “an implementation”, as well as other variations thereof, means that a particular feature, structure, characteristic, and so forth described in connection with the embodiment is included in at least one embodiment. Thus, the appearances of the phrase “in one embodiment” or “in an embodiment” or “in one implementation” or “in an implementation”, as well any other variations, appearing in various places throughout this application are not necessarily all referring to the same embodiment.

Additionally, this application may refer to “determining” various pieces of information. Determining the information can include one or more of, for example, estimating the information, calculating the information, predicting the information, or retrieving the information from memory.

Further, this application may refer to “accessing” various pieces of information. Accessing the information can include one or more of, for example, receiving the information, retrieving the information (for example, from memory), storing the information, moving the information, copying the information, calculating the information, determining the information, predicting the information, or estimating the information.

Additionally, this application may refer to “receiving” various pieces of information. Receiving is, as with “accessing”, intended to be a broad term. Receiving the information can include one or more of, for example, accessing the information, or retrieving the information (for example, from memory). Further, “receiving” is typically involved, in one way or another, during operations such as, for example, storing the information, processing the information, transmitting the information, moving the information, copying the information, erasing the information, calculating the information, determining the information, predicting the information, or estimating the information.

It is to be appreciated that the use of any of the following “l”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This may be extended, as is clear to one of ordinary skill in this and related arts, for as many items as are listed.

Also, as used herein, the word “signal” refers to, among other things, indicating something to a corresponding decoder. For example, in certain embodiments the encoder signals a particular one of a plurality of transforms, coding modes or flags. In this way, in an embodiment the same transform, parameter, or mode is used at both the encoder side and the decoder side. Thus, for example, an encoder can transmit (explicit signaling) a particular parameter to the decoder so that the decoder can use the same particular parameter. Conversely, if the decoder already has the particular parameter as well as others, then signaling can be used without transmitting (implicit signaling) to simply allow the decoder to know and select the particular parameter. By avoiding transmission of any actual functions, a bit savings is realized in various embodiments. It is to be appreciated that signaling can be accomplished in a variety of ways. For example, one or more syntax elements, flags, and so forth are used to signal information to a corresponding decoder in various embodiments. While the preceding relates to the verb form of the word “signal”, the word “signal” can also be used herein as a noun.

As will be evident to one of ordinary skill in the art, implementations can produce a variety of signals formatted to carry information that can be, for example, stored or transmitted. The information can include, for example, instructions for performing a method, or data produced by one of the described implementations. For example, a signal can be formatted to carry the bitstream of a described embodiment. Such a signal can be formatted, for example, as an electromagnetic wave (for example, using a radio frequency portion of spectrum) or as a baseband signal. The formatting can include, for example, encoding a data stream and modulating a carrier with the encoded data stream. The information that the signal carries can be, for example, analog or digital information. The signal can be transmitted over a variety of different wired or wireless links, as is known. The signal can be stored on a processor-readable medium.

Although the present embodiments have been described hereinabove with reference to specific embodiments, the present disclosure is not limited to the specific embodiments, and modifications will be apparent to a skilled person in the art which lie within the scope of the claims.

Many further modifications and variations will suggest themselves to those versed in the art upon making reference to the foregoing illustrative embodiments, which are given by way of example only and which are not intended to limit the scope of the disclosure, that being determined solely by the appended claims. In particular, the different features from different embodiments may be interchanged where appropriate.

We describe a number of embodiments, across various claim categories and types. Features of these embodiments can be provided alone or in any combination. Further, embodiments can include one or more of the following features, devices, or aspects, alone or in any combination, across various claim categories and types:
A process or device to perform encoding and decoding with deep neural network compression of a pre-trained deep neural network.
A process or device to perform encoding and decoding with inserted information in a bitstream representative of parameters to implement deep neural network compression of a pre-trained deep neural network comprising one or more layers.
A process or device to perform encoding and decoding with inserted information in a bitstream representative of parameters to implement deep neural network compression of a pre-trained deep neural network until a compression criterion is reached.
A bitstream or signal that includes one or more of the described syntax elements, or variations thereof.
A bitstream or signal that includes syntax conveying information generated according to any of the embodiments described.
Creating and/or transmitting and/or receiving and/or decoding according to any of the embodiments described.
A method, process, apparatus, medium storing instructions, medium storing data, or signal according to any of the embodiments described.
Inserting in the signaling syntax elements that enable the decoder to determine coding mode in a manner corresponding to that used by an encoder.
Creating and/or transmitting and/or receiving and/or decoding a bitstream or signal that includes one or more of the described syntax elements, or variations thereof.
A TV, set-top box, cell phone, tablet, or other electronic device that performs transform method(s) according to any of the embodiments described.
A TV, set-top box, cell phone, tablet, or other electronic device that performs transform method(s) determination according to any of the embodiments described, and that displays (e.g. using a monitor, screen, or other type of display) a resulting image.
A TV, set-top box, cell phone, tablet, or other electronic device that selects, bandlimits, or tunes (e.g. using a tuner) a channel to receive a signal including an encoded image, and performs transform method(s) according to any of the embodiments described.
A TV, set-top box, cell phone, tablet, or other electronic device that receives (e.g. using an antenna) a signal over the air that includes an encoded image, and performs transform method(s).

1. A method, comprising:
determining neural network training data from a neural network data set;
obtaining inputs and outputs of layers of a neural network based on the neural network training data;
compressing at least one layer of the neural network using said inputs and outputs to obtain parameters representing weights and biases corresponding to said layers; and
storing or transmitting said compressed parameters in a bitstream.

2. An apparatus, comprising:
a processor, configured to:
determine neural network training data from a neural network data set;
obtain inputs and outputs of layers of a neural network based on the neural network training data;
compress at least one layer of the neural network using said inputs and outputs to obtain parameters representing weights and biases corresponding to said layers; and
store or transmit said compressed parameters in a bitstream.

3. A method, comprising:
extracting symbols from a bitstream;
inverse quantizing said symbols;
obtaining matrix weights for at least one neural network layer from said inverse quantized symbols; and
reconstructing a neural network from said obtained matrix weights for the at least one neural network layer.

4. An apparatus, comprising:
a processor, configured to:
extract symbols from a bitstream;
inverse quantize said symbols;
obtain matrix weights for at least one neural network layer from said inverse quantized symbols; and
reconstruct a neural network from said obtained matrix weights for the at least one neural network layer.

5. The method of claim 1, wherein said neural network training data is obtained based on a subset of training data used for training the neural network.

6. The method of claim 1, further comprising,
quantizing said weights and biases corresponding to the layers of the neural network.

7. The method of claim 1, wherein said neural network training data comprises set examples on the neural network.

8. The method of claim 1, wherein said bitstream further comprises metadata indicative of non-linearities.

9. The method of claim 1, wherein said compression is performed for a fixed number of layers.

10. The apparatus of claim 4, further comprising:
at least one of (i) an antenna configured to receive a signal, the signal including the bitstream, (ii) a band limiter configured to limit the received signal to a band of frequencies that includes the bitstream, and (iii) a display configured to display an output representative of said signal.

11. (canceled)

12. (canceled)

13. A computer program product comprising instructions which, when the program is executed by a computer, cause the computer to carry out the method comprising:
determining neural network training data from a neural network data set;
obtaining inputs and outputs of layers of a neural network based on the neural network training data;
compressing at least one layer of the neural network using said inputs and outputs to obtain parameters representing weights and biases corresponding to said layers; and
storing or transmitting said compressed parameters in a bitstream.

14. The apparatus of claim 2, wherein said neural network training data is obtained based on a subset of training data used for training the neural network.

15. The apparatus of claim 2, the processor further configured to quantize said weights and biases corresponding to the layers of the neural network.

16. The apparatus of claim 2, wherein said neural network training data comprises set examples on the neural network.

17. The apparatus of claim 2, wherein said bitstream further comprises metadata indicative of non-linearities.

18. The apparatus of claim 2, wherein said compression is performed for a fixed number of layers.
